(19) United States
(12) Patent Application Publication
(10) Pub. No.: US 2024/0306443 A1
(43) Pub. Date: Sep. 12, 2024

(54) DISPLAY BASEPLATE AND MANUFACTURING METHOD THEREOF, AND DISPLAY DEVICE

(71) Applicants: Chengdu BOE Optoelectronics Technology Co., Ltd., Chengdu, Sichuan (CN); BOE TECHNOLOGY GROUP CO., LTD., Beijing (CN)

(72) Inventors: Hongjun Zhou, Beijing (CN); Juntao Chen, Beijing (CN); Zhenli Zhou, Beijing (CN); Chengjie Qin, Beijing (CN); Yudiao Cheng, Beijing (CN); Quan Shi, Beijing (CN)

(73) Assignees: Chengdu BOE Optoelectronics Technology Co., Ltd., Chengdu, Sichuan (CN); BOE TECHNOLOGY GROUP CO., LTD., Beijing (CN)

(21) Appl. No.: 18/027,560

(22) PCT Filed: Jun. 23, 2022
(86) PCT No.: PCT/CN2022/100668

§ 371 Date: Mar. 21, 2023

(51) Int. Cl. H10K 59/131; H10K 59/12; H10K 59/122

(52) U.S. Cl. CPC H10K 59/131; H10K 59/1201; H10K 59/122

(57) ABSTRACT

A display baseplate and a manufacturing method thereof, and a display device, relate to the technical field of displaying. The display baseplate includes an active area and a border area located on at least one side of the active area. The border area includes: a substrate; and a first conductive layer disposed on one side of the substrate; wherein at least one first opening is disposed on the first conductive layer, and the orthographic projection of the first conductive layer on the substrate does not overlap with an orthographic projection of the at least one first opening on the substrate.

### TECHNICAL FIELD

The present disclosure relates to the technical field of displaying, and more particularly to a display baseplate and manufacturing method thereof, and a display device.

### BACKGROUND

Organic light emitting diodes (OLED) are active light-emitting devices with the advantages such as self-luminescence, wide viewing angle, fast reaction time, high light-emitting efficiency, low working voltage, and simple processing, and are known as the next generation of “star” light-emitting devices.

### SUMMARY

The present disclosure provides a display baseplate including an active area and a border area located on at least one side of the active area. The border area includes:
a substrate; and
a first conductive layer disposed on one side of the substrate;
wherein at least one first opening is disposed on the first conductive layer, and an orthographic projection of the first conductive layer on the substrate does not overlap with an orthographic projection of the at least one first opening on the substrate.

In an alternative implementation, the border area further includes:
a flat layer disposed on one side of the first conductive layer away from the substrate;
a pixel definition layer disposed on one side of the flat layer away from the substrate; and
a spacer layer provided on one side of the pixel definition layer away from the substrate, wherein the spacer layer includes a plurality of first spacer columns separated from each other;
wherein orthographic projections of the plurality of first spacer column on the substrate, an orthographic projection of the pixel definition layer on the substrate, and an orthographic projection of the flat layer on the substrate overlap with each other.

In an alternative implementation, the orthographic projections of the plurality of first spacer columns on the substrate is within a range of the orthographic projection of the pixel definition layer on the substrate, and the orthographic projection of the pixel definition layer on the substrate is within a range of the orthographic projection of the flat layer on the substrate.

In an alternative implementation, the border area further includes:
a second conductive layer located between the flat layer and the pixel definition layer;
wherein at least one second opening is disposed on the second conductive layer, an orthographic projection of the second conductive layer on the substrate does not overlap with an orthographic projection of the at least one second opening on the substrate, and the orthographic projection of the at least one second opening on the substrate is within a range of the orthographic projection of the flat layer on the substrate.

In an alternative implementation, the orthographic projection of the pixel definition layer on the substrate covers the orthographic projection of the at least one second opening on the substrate and its boundary.

In an alternative implementation, the first conductive layer includes a first lapping pattern, and orthographic projection of the first lapping pattern and the flat layer on the substrate do not overlap; the orthographic projections of the second conductive layer and the first lapping pattern on the substrate overlap, and the second conductive layer and the first lapping pattern lap each other.

In an alternative implementation, a ratio of an area of the orthographic projection of the at least one second opening on the substrate to an overlapping area is greater than or equal to 0.15, and less than or equal to 0.6;
wherein the overlapping area is an area of a region where the orthographic projections of the flat layer and the second conductive layer on the substrate overlap with each other.

In an alternative implementation, the border area further includes:
a third conductive layer located on one side of the spacer layer away from the substrate;
wherein the second conductive layer includes a second lapping pattern, and orthographic projections of the second lapping pattern, the pixel definition layer, and the spacer layer on the substrate do not overlap; orthographic projections of the third conductive layer and the second lapping pattern on the substrate overlap, and the third conductive layer and the second lapping pattern lap each other.

In an alternative implementation, the orthographic projection of the flat layer on the substrate covers the orthographic projection of the at least one first opening on the substrate and its boundary.

In an alternative implementation, the border area includes a first wiring region and a second wiring region, the first wiring region is located between the active area and the second wiring region; the border area further includes:
a drive circuit disposed between the substrate and the flat layer;
wherein the drive circuit is located in the first wiring area, the first conductive layer is located in the second wiring area, and the orthographic projection of the flat layer on the substrate covers the first wiring area.

In an alternative implementation, the plurality of first spacer columns are located in the first wiring area and/or the second wiring area.

In an alternative implementation, the spacer layer further includes a plurality of second spacer columns separated from each other, the plurality of second spacer columns are located in the active area;
wherein a height of a surface of one side of the second spacer column away from the substrate is consistent with a height of a surface of one side of the first spacer column away from the substrate.

In an alternative implementation, a distribution density of the first spacer column is less than or equal to a distribution density of the second spacer column in a direction parallel to a plane where the substrate is located.

In an alternative implementation, the display baseplate further includes an encapsulation area located on one side of the border area away from the active area; and
a minimum distance between the first spacer column and the encapsulation area in a direction parallel to a plane where the substrate is located is less than or equal to 600 microns.

In an alternative implementation, a size of the first opening is greater than or equal to 3 microns and less than or equal to 30 microns in a direction parallel to a plane where the substrate is located.

In an alternative implementation, a minimum distance between two first openings in a direction parallel to a plane where the substrate is located is greater than or equal to 10 microns.

In an alternative implementation, a ratio of an area of the orthographic projection of the at least one first opening on the substrate and an area of the orthographic projection of the first conductive layer on the substrate is less than or equal to 0.5.

In an alternative implementation, a shape of the orthographic projection of the first opening on the substrate includes at least one of polygons, chamfered polygons, circles, ellipses, and sectors.

The present disclosure provides a display device, including:
the display baseplate according to any one as described above;
a driving integrated circuit configured to provide a driving signal to the display baseplate; and
a power supply circuit configured to supply power to the display baseplate.

The present disclosure provides a manufacturing method for a display baseplate, wherein the display baseplate includes an active area and a border area located on at least one side of the active area, and the manufacturing method for the border area includes:
providing a substrate; and
forming a first conductive layer on one side of the substrate; wherein at least one first opening is disposed on the first conductive layer, and an orthographic projection of the first conductive layer on the substrate does not overlap with the orthographic projection of the at least one first opening on the substrate.

The above description is merely an overview of the technical solutions of the present disclosure, which can be carried out in accordance with the contents of the description in order to make the technical means of the present disclosure more clearly understood. In order to make the above and other objects, features, and advantages of the present disclosure more apparent, specific implementation modes of the present disclosure are set forth below.

### BRIEF DESCRIPTION OF THE DRAWINGS

In order to illustrate the embodiments of the present disclosure or the technical solutions in the related art more clearly, the following will briefly introduce the drawings that need to be used in the description of the embodiments or the related art. Obviously, the drawings in the following description are some embodiments of the present disclosure. For those of ordinary skills in the art, other drawings can be obtained according to these drawings without involving inventive efforts. It needs to be noted that the proportions shown in the figures are merely schematic and do not represent actual proportions.

FIG. 1 schematically shows a schematic cross-sectional structural diagram of a display baseplate in the related art;

FIG. 2 is a schematic diagram schematically showing the electrostatic discharge of a wiring at a border area in the related art;

FIG. 3 schematically shows a schematic diagram of a planar structure of a display baseplate provided by the present disclosure;

FIG. 4 schematically shows a schematic cross-sectional structural diagram of a display baseplate provided by the present disclosure;

FIG. 5 schematically shows a schematic cross-sectional structural diagram of another display baseplate provided by the present disclosure;

FIG. 6 schematically shows a schematic diagram of a planar structure of a first conductive layer;

FIG. 7 schematically shows a schematic diagram of a planar structure of a flat layer;

FIG. 8 schematically shows a schematic diagram of a planar structure of a second conductive layer;

FIG. 9 schematically shows a schematic diagram of a planar structure of a pixel definition layer;

FIG. 10 schematically shows a schematic diagram of a planar structure of a spacer layer;

FIG. 11 schematically shows a schematic diagram of a planar structure of a stacked structure constructed by a first conductive layer and a flat layer;

FIG. 12 schematically shows a schematic diagram of a planar structure of a stacked structure constructed by a first conductive layer, a flat layer, and a second conductive layer;

FIG. 13 schematically shows a schematic diagram of a planar structure of a stacked structure constructed by a first conductive layer, a flat layer, a second conductive layer, and a pixel definition layer;

FIG. 14 schematically shows a schematic diagram of a planar structure of a stacked structure constructed by a first conductive layer, a flat layer, a second conductive layer, a pixel definition layer, and a spacer layer;

FIG. 15 schematically shows a schematic diagram of a planar structure of a second wiring area; and

FIG. 16 schematically shows a schematic diagram of a planar structure of a border area and an encapsulation area.

### DETAILED DESCRIPTION

In order to make the purposes, technical solutions, and advantages of the embodiments of the present disclosure clearer, the technical solutions in the embodiments of the present disclosure will be clearly and completely described below in conjunction with the accompanying drawings in the embodiments of the present disclosure. Obviously, the described embodiments are a part of the embodiments of the present disclosure, rather than all the embodiments. Based on the embodiments of the present disclosure, all other embodiments obtained by one of ordinary skills in the art without involving any inventive effort are within the scope of the present disclosure.

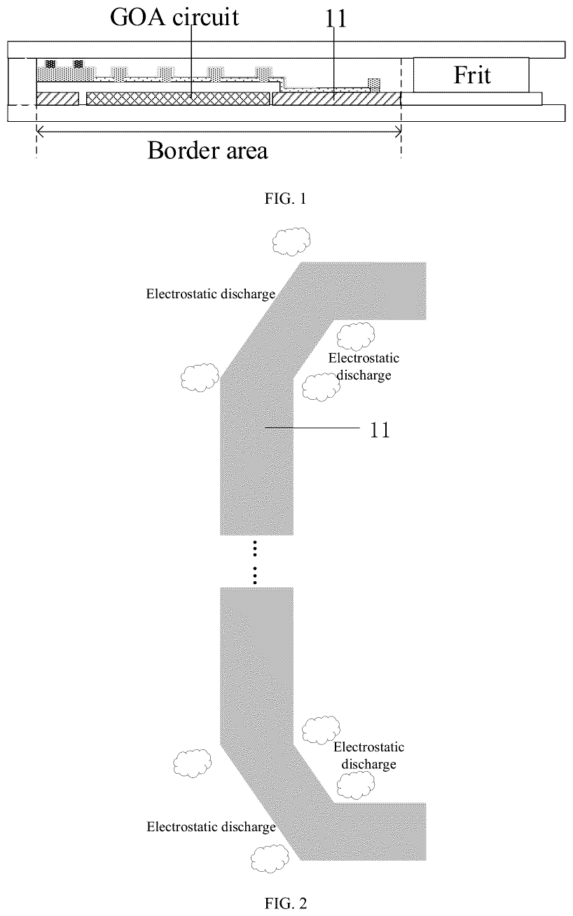

In the related art, as shown in FIG. 1, a signal wiring 11 is provided in a border area of a display baseplate. When the size of the display baseplate is large or the drive current is large, a wide signal wiring 11 is typically designed to reduce the effect of IR Drop.

The inventors have found that an excessively wide signal wiring 11 may increase the risk of electrostatic breakdown. The reason is that static electricity may be introduced during the manufacturing or daily use of the display baseplate, and the wider the signal wiring 11 is, the easier it is to accumulate electrostatic charge. Since electrostatic discharge tends to occur at a corner location of the signal wiring 11, as shown in FIG. 2, electrostatic breakdown of adjacent circuit structures, such as GOA circuits, thus may be caused.

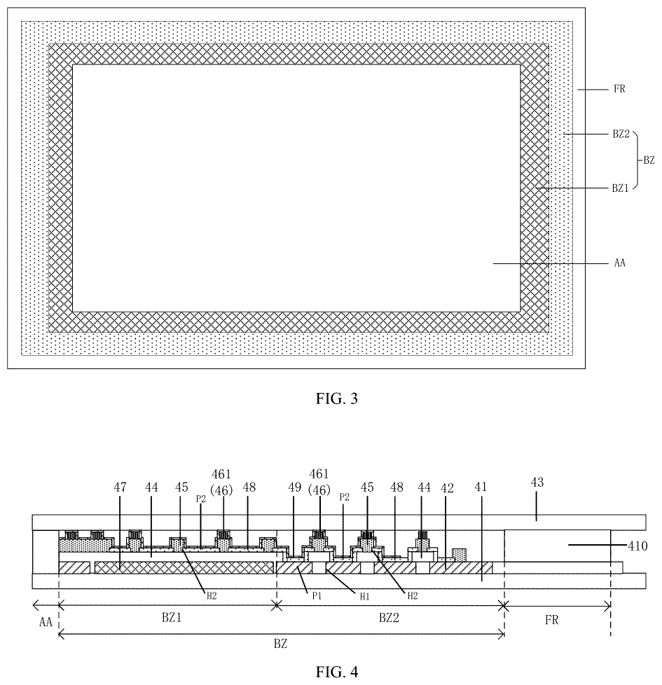

The present disclosure provides a display baseplate. Referring to FIG. 3, which schematically shows a schematic diagram of a planar structure of a display baseplate provided by the present disclosure. As shown in FIG. 3, the display baseplate includes an active area AA and a border area BZ located on at least one side of the active area AA. The border area BZ may surround the active area AA, as shown in FIG. 3.

Referring to FIG. 4 which schematically shows a schematic cross-sectional structural diagram of a display baseplate provided by the present disclosure. As shown in FIG. 4, the display baseplate of the border area BZ includes: a substrate 41; and a first conductive layer 42 disposed on one side of the substrate 41.

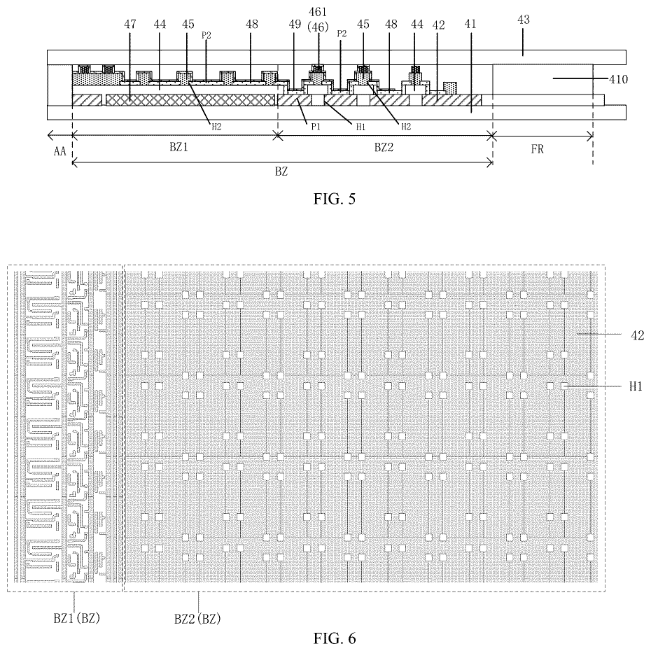

Refer to FIG. 6, which schematically shows a schematic diagram of a planar structure of a kind of first conductive layer 42. As shown in FIG. 4 or FIG. 6, at least one first opening H1 is disposed on the first conductive layer 42, and the orthographic projection of the first conductive layer 42 on the substrate 41 does not overlap with the orthographic projection of the first opening H1 on the substrate 41.

In the display baseplate provided by the present disclosure, multiple corners may be formed inside the first conductive layer 42 by providing one or more first openings H1 on the first conductive layer 42, which is equivalent to adding an electrostatic discharge path inside the first conductive layer 42, so that the electrostatic charge accumulated on the first conductive layer 42 can be discharged at inner corners of the first conductive layer 42, thereby reducing the probability of electrostatic damage to adjacent circuits caused by electrostatic discharge at outer corners of the first conductive layer 42.

The number of the first openings H1 disposed on the first conductive layer 42 may be one or more, which is not limited by the present disclosure.

In some illustrative implementation, as shown in FIG. 4, the first opening H1 passes through the first conductive layer 42 in a direction perpendicular to the plane where the substrate 41 is located.

In a specific implementation, the first opening H1 may be disposed on each of the first conductive layers 42 in any size (in a direction parallel to the plane where the substrate 41 is located). By disposing the first opening H1 on the first conductive layer 42 having a large size (e.g., a width of ≥400 μm in a direction parallel to the plane where the substrate 41 is located), the disadvantage of electrostatic damage may be more significantly improved.

In some illustrative implementation, the size of the first opening H1 may be greater than or equal to 3 microns and less than or equal to 30 microns in a direction parallel to the plane where the substrate 41 is located.

In some illustrative implementation, the shape of the orthographic projection of the first opening H1 on the substrate 41 may include at least one of: regular and irregular patterns such as polygons, chamfered polygons, circles, ellipses, and sectors. The polygons may include triangles, rectangles, squares, trapezoids, parallelograms, diamonds, pentagons, hexagons, etc.

In the first conductive layer 42 shown in FIG. 6, the shape of the orthographic projection of the first opening H1 on the substrate 41 is a square, and a side length of the square is 14 microns.

In some illustrative implementation, the minimum distance between two first openings H1 in a direction parallel to the plane where the substrate 41 is located is greater than or equal to 10 microns, so that the formation of a narrow linewidth wiring between the two first openings H1 can be avoided which otherwise results in increased resistance, thus reducing IR Drop effect.

In some illustrative implementation, the ratio of the area of the orthographic projection of the at least one first opening H1 on the substrate 41 to the area of the orthographic projection of the first conductive layer 42 on the substrate 41 is less than or equal to 0.5.

The area of the orthographic projection of the above-mentioned at least one first opening H1 on the substrate 41 refers to the area of the orthographic projection of all the first openings H1 disposed on the first conductive layer 42 on the substrate 41.

By setting the ratio of the area of the orthographic projection of all the first openings H1 on the substrate 41 to the area of the orthographic projection of the first conductive layer 42 on the substrate 41 to be less than or equal to 0.5, the scenario that the size of the first conductive layer 42 is excessively reduced due to the excessive total area of the first openings H1 can be avoided, which reduces the IR Drop effect.

In some illustrative implementation, as shown in FIG. 4, the above-described display baseplate may further include: an encapsulation glass 43 disposed on the side of the first conductive layer 42 away from the substrate 41.

The inventors have found that the border area BZ disposed at the periphery of the active area AA is prone to the phenomenon of ring-shaped unevenness of display, i.e., poor Newton's ring. The main causes of poor Newton's ring are as follows: the film thicknesses of the active area AA and the border area BZ (namely, the film thicknesses disposed between the substrate 41 and the encapsulation glass 43) are inconsistent, resulting in the distance between the substrate 41 and the encapsulation glass 43 respectively having different values in the active area AA and the border area BZ, and finally resulting in a poor Newton's ring.

In some illustrative implementation, the display baseplate of the border area BZ may further include: a flat layer 44 disposed on a side of the first conductive layer 42 away from the substrate 41; a pixel definition layer 45 provided on a side of the flat layer 44 away from the substrate 41; and a spacer layer 46 provided on a side of the pixel definition layer 45 away from the substrate 41.

Referring to FIG. 10, which schematically shows a schematic diagram of a planar structure of a spacer layer 46. As shown in FIG. 4 or FIG. 10, the spacer layer 46 includes a plurality of first spacer columns 461 separated from each other.

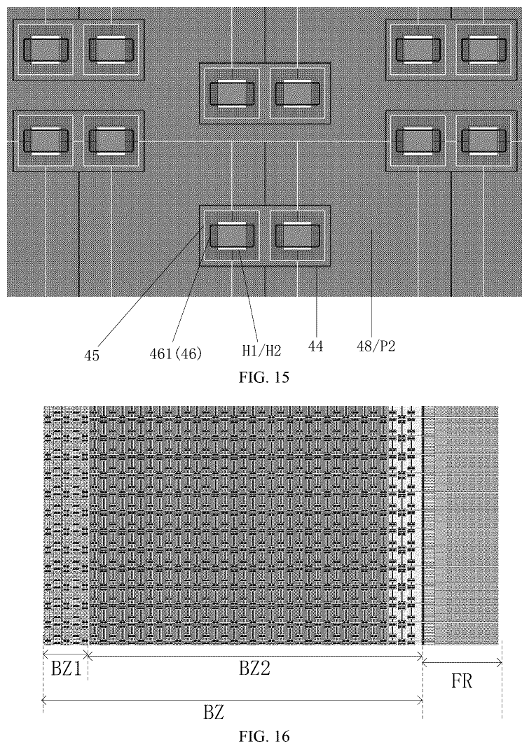

FIG. 15 schematically shows a schematic diagram of a planar structure of part of a border area BZ. As shown in FIG. 4 or FIG. 15, the orthographic projection of the first spacer column 461 on the substrate 41, the orthographic projection of the pixel definition layer 45 on the substrate 41, and the orthographic projection of the flat layer 44 on the substrate 41 overlap each other.

By stacking the flat layer 44, the pixel definition layer 45, and the spacer layer 46 on one side of the first conductive layer 42 away from the substrate 41 in the border area BZ, the difference between the film thickness of the border area BZ and the film thickness of the active area AA can be reduced, so that the distance between the substrate 41 and the encapsulation glass 43 that are located in the active area AA is close to the distance between the substrate 41 and the encapsulation glass 43 that are located in the border area BZ. Therefore, poor Newton's ring may be improved.

In a specific implementation, the first conductive layer 42 may extend to the active area AA for forming a signal line, such as grid line or data line, within the active area AA. The flat layer 44 may extend to the active area AA for planarizing the surface of the active area AA. The pixel definition layer 45 may extend to the active area AA for defining a plurality of pixel openings forming in the active area AA, and the pixel openings are used for disposing light emitting devices. The spacer layer 46 may extend to the active area AA for forming a second spacer column of the active area AA.

The surface of one side of the first spacer column 461 away from the substrate 41 serves to support the encapsulation glass 43.

Alternatively, as shown in FIG. 4 or FIG. 15, the orthographic projection of the first spacer column 461 on the substrate 41 is located within a range of the orthographic projection of the pixel definition layer 45 on the substrate 41, and the orthographic projection of the pixel definition layer 45 on the substrate 41 is located within a range of the orthographic projection of the flat layer 44 on the substrate 41.

In some illustrative implementation, as shown in FIG. 3, the border area BZ includes a first wiring area BZ1 and a second wiring area BZ2, and the first wiring area BZ1 is located between the active area AA and the second wiring area BZ2.

In some illustrative implementation, as shown in FIG. 4, the border area BZ further includes: a drive circuit 47 disposed between the substrate 41 and the flat layer 44.

The drive circuit 47 is located in the first wiring area BZ1, and the first conductive layer 42 is located in the second wiring area BZ2.

In order to insulate the drive circuit 47 from subsequent conductive films (such as the second conductive layer 48), the orthographic projection of the flat layer 44 on the substrate 41 may cover the drive circuit 47. Further, the orthographic projection of the flat layer 44 on the substrate 41 may cover the first wiring area BZ1.

Alternatively, the drive circuit 47 is a gate drive circuit (Gate on Array, GOA).

Alternatively, the plurality of first spacer columns 461 are located in the first wiring area BZ1 and/or the second wiring area BZ2.

In a specific implementation, a first spacer column 461 may be disposed only in the first wiring area BZ1; or the first spacer column 461 is disposed only in the second wiring area BZ2; alternatively, the first spacer column 461 may be disposed in both the first wiring area BZ1 and the second wiring area BZ2.

For example, when the width of the first wiring area BZ1 is less than or equal to 400 μm in a direction parallel to the plane where the substrate 41 is located, the first spacer column 461 may be disposed only in the second wiring area BZ2, as shown in FIG. 5; when the width of the second wiring area BZ2 is less than or equal to 400 μm, the first spacer column 461 may be disposed only in the first wiring area BZ1.

In some illustrative implementation, the spacer layer 46 may further include a plurality of second spacer columns (not shown) separated from each other, and the plurality of second spacer columns are located in the active area AA.

In a specific implementation, the substrate 41, the flat layer 44, the pixel definition layer 45, the spacer layer 46, and the encapsulation glass 43 may all extend to the active area AA. Within the active area AA, the flat layer 44, the pixel definition layer 45, and the second spacer column are stacked between the substrate 41 and the encapsulation glass 43. The surface of one side of the second spacer column away from the substrate 41 serves to support the encapsulation glass 43.

The difference in heights between the surface of one side of the second spacer column away from the substrate 41 and the surface of one side of the first spacer column 461 away from the substrate 41 is less than or equal to 10% or 5%.

Further, the height of the surface of one side of the second spacer column away from the substrate 41 is consistent with the height of the surface of one side of the first spacer column 461 away from the substrate 41. In this way, it may ensure that the film thickness between the substrate 41 and the encapsulation glass 43 in the border area BZ is consistent with the film thickness between the substrate 41 and the encapsulation glass 43 in the active area AA, so that the distance between the substrate 41 and the encapsulation glass 43 has consistent values in the active area AA and the border area BZ. Therefore, poor Newton's ring can be completely eliminated.

In some illustrative implementation, the distribution density of the first spacer column 461 is less than or equal to the distribution density of the second spacer column in a direction parallel to the plane where the substrate 41 is located.

Alternatively, the distribution density of the first spacer column 461 may be ⅓, ½, or ⅔, etc. of the distribution density of the second spacer column, which may be specifically set according to actual requirements.

In this way, the film thickness of the border area BZ and the film thickness of the active area AA can be ensured to be consistent, and the adhesion of the first spacer column 461 to the evaporation mask plate can be avoided, so that the evaporation mask plate can be quickly removed after the evaporation is completed.

Alternatively, the distribution density of the first spacer column 461 within the first wiring area BZ1 may be the same as the distribution density of the first spacer column 461 within the second wiring area BZ2, as shown in FIG. 10.

Alternatively, the distribution density of the first spacer column 461 in the first wiring area BZ1 may be different from the distribution density of the first spacer column 461 in the second wiring area BZ2. Further, the distribution density of the first spacer column 461 within the first wiring area BZ1 may be greater than or equal to the distribution density of the first spacer column 461 within the second wiring area BZ2.

Alternatively, the orthographic projection of the first spacer column 461 on the substrate 41 is the same in shape as the orthographic projection of the second spacer column on the substrate 41.

Alternatively, the orthographic projection of the first spacer column 461 on the substrate 41 is the same in size as the orthographic projection of the second spacer column on the substrate 41.

Alternatively, the orthographic projection of the first spacer column 461 on the substrate 41 is arranged with the same period as the orthographic projection of the second spacer column on the substrate 41.

In some illustrative implementation, as shown in FIG. 4 or FIG. 16, the display baseplate further includes an encapsulation area FR on one side of the border area BZ away from the active area AA.

Alternatively, the minimum distance between the first spacer column 461 and the encapsulation area FR in a direction parallel to the plane where the substrate base pale 41 is located is less than or equal to 600 microns.

Further, the minimum distance between the first spacer column 461 and the encapsulation area FR may be less than or equal to 500 microns, 400 microns, 300 microns, 200 microns, 100 microns, or 50 microns, etc. in a direction parallel to the plane where the substrate base pale 41 is located, which is not limited by the present disclosure.

Alternatively, as shown in FIG. 4, in the encapsulation area FR, the display baseplate includes a glass cement 410 packaged between the substrate 41 and the encapsulation glass 43, and the glass cement 410 is used for blocking the intrusion of external water and oxygen so as to realize Frit encapsulation.

In FIG. 4, the minimum distance between the first spacer column 461 and the encapsulation area FR may be the minimum distance between the first spacer column 461 and the glass cement 410.

In some illustrative implementation, as shown in FIG. 4, the display baseplate of the border area BZ may further include: a second conductive layer 48 located between the flat layer 44 and the pixel definition layer 45.

Referring to FIG. 8, which schematically shows a schematic diagram of a planar structure of a second conductive layer 48. As shown in FIG. 4 or FIG. 8, at least one second opening H2 is disposed on the second conductive layer 48, and the orthographic projection of the second conductive layer 48 on the substrate 41 does not overlap with the orthographic projection of the second opening H2 on the substrate 41.

Referring to FIG. 12, which schematically shows a schematic diagram of a planar structure of a stacked structure constructed by a first conductive layer 42, a flat layer 44, and a second conductive layer 48. As shown in FIG. 4 or FIG. 12, the orthographic projection of the second opening H2 on the substrate 41 is within the range of the orthographic projection of the flat layer 44 on the substrate 41.

By disposing the second opening H2 on the second conductive layer 48 at a position corresponding to the flat layer 44, a partial area on the flat layer 44 is not covered by the second conductive layer 48. When the flat layer 44 contains organic material, the exhaust gas generated by the flat layer 44 during the manufacturing process of the display baseplate can be released through the second opening H2, helping to improve the film adhesion.

The second conductive layer 48 may extend to the active area AA for forming a conductive pattern within the active area AA, such as an anode of a light emitting device or the like.

In some illustrative implementation, as shown in FIG. 4, the second opening H2 passes through the second conductive layer 48 in a direction perpendicular to the plane where the substrate 41 is located.

In some illustrative implementation, as shown in FIG. 4, a plurality of second openings H2 may be uniformly disposed on the second conductive layer 48, so that the exhaust gas generated at each position of the flat layer 44 can be timely released, thus increasing the release rate of the exhaust gas.

The center of the orthographic projection of the first opening H1 on the substrate 41 and the center of the orthographic projection of the second opening H2 on the substrate 41 may or may not coincide. The shape of the orthographic projection of the first opening H1 on the substrate 41 may or may not coincide with the shape of the orthographic projection of the second opening H2 on the substrate 41. The size of the orthographic projection of the first opening H1 on the substrate 41 may or may not coincide with the size of the orthographic projection of the second opening H2 on the substrate 41.

FIG. 13 schematically shows a schematic diagram of a planar structure of a stacked structure constructed by a first conductive layer 42, a flat layer 44, a second conductive layer 48, and a pixel definition layer 45. As shown in FIG. 4 or FIG. 13, the orthographic projection of the pixel definition layer 45 on the substrate 41 covers the orthographic projection of the second opening H2 on the substrate 41 and its boundary.

By arranging the pixel definition layer 45 to cover the edge of the second opening H2, bare failure of the second conductive layer 48 at the edge can be avoided, and static electricity can be prevented from being released at the edge of the second conductive layer 48, which would otherwise damage the light emitting device.

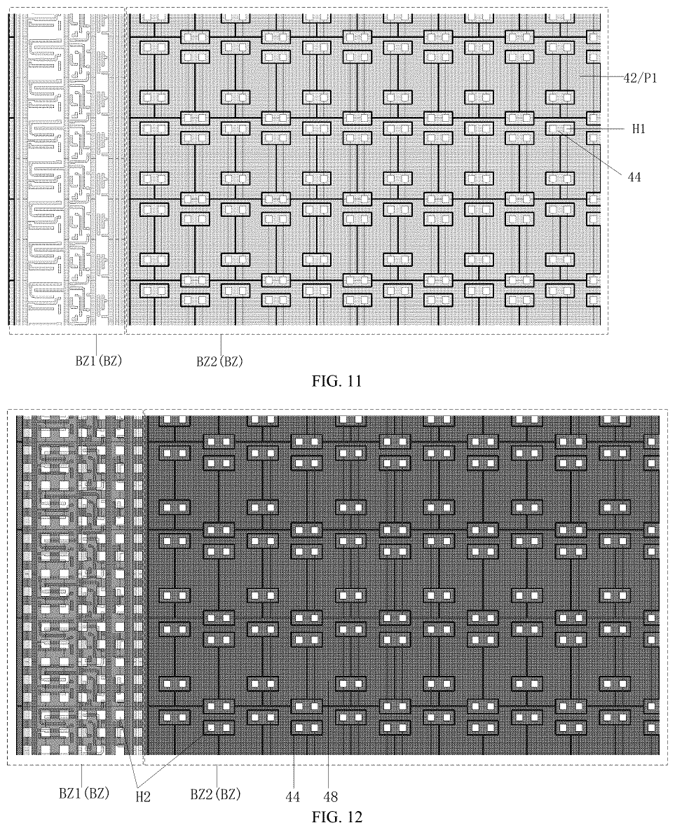

Alternatively, referring to FIG. 11, which schematically shows a schematic diagram of a planar structure of a stacked structure constructed by a first conductive layer 42 and a flat layer 44. As shown in FIG. 4 or FIG. 11, the first conductive layer 42 includes a first lapping pattern P1, and the orthographic projections of the first lapping pattern P1 and the flat layer 44 on the substrate 41 do not overlap; the orthographic projections of the second conductive layer 48 and the first lapping pattern P1 on the substrate 41 overlap, and the second conductive layer 48 and the first lapping pattern P1 lap each other.

As shown in FIG. 4 or FIG. 11, the first lapping pattern P1 is an area of the first conductive layer 42 that is not covered by the flat layer 44. The transmission of a signal from the first conductive layer 42 to the second conductive layer 48 can be achieved by arranging the second conductive layer 48 and the first lapping pattern P1 to lap.

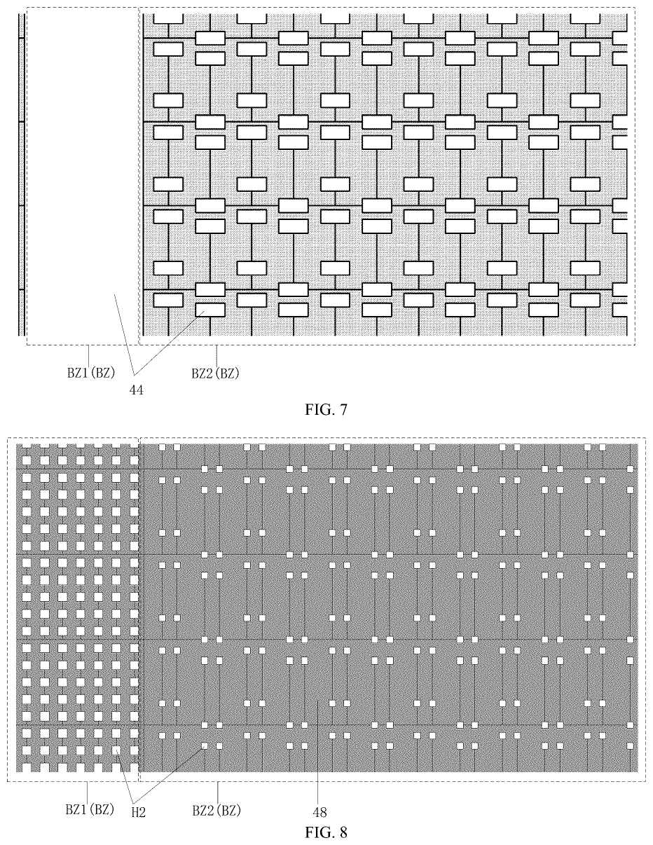

Referring to FIG. 7, which schematically shows a schematic diagram of a planar structure of a kind of flat layer 44. As shown in FIG. 4, FIG. 7, or FIG. 11, in the flat layer 44, a pattern for covering the edge of the first opening H1 is disposed only at an edge position of the first opening H1, and the flat layers 44 in other areas are all dug up, so that the lapping area between the first conductive layer 42 and the second conductive layer 48 can be increased and the IR Drop effect can be reduced.

Alternatively, the ratio of the area of the orthographic projection of the at least one second opening H2 on the substrate 41 to the overlapping area is greater than or equal to 0.15 and is less than or equal to 0.6.

The overlapping area is the area of a region where the orthographic projections of the flat layer 44 and the second conductive layer 48 on the substrate 41 respectively overlap with each other. The area of the orthographic projection of the at least one second opening H2 on the substrate 41 refers to the area of the orthographic projection of all the second openings H2 disposed on the second conductive layer 48 on the substrate 41.

By disposing that the ratio of the area of the orthographic projection of all the second opening H2 on the substrate 41 to the overlapping area is greater than or equal to 0.15 and is less than or equal to 0.6, it may avoid excessive hole-digging on the second conductive layer 48 and reduce the IR Drop effect under the premise of ensuring that the exhaust gas generated by the flat layer 44 can be released in time.

As shown in FIG. 8, in the first wiring area BZ1, since the overlapping area between the flat layer 44 and the second conductive layer 48 is large, a larger number of second openings H2 are disposed on the second conductive layer 48 in the first wiring area BZ1; in the second wiring area BZ2, a small number of second openings H2 are disposed on the second conductive layer 48 in the second wiring area BZ2 due to the small overlapping area between the flat layer 44 and the second conductive layer 48.

In some illustrative implementation, as shown in FIG. 4, the border area BZ further includes: a third conductive layer 49 located on one side of the spacer layer 46 away from the substrate 41.

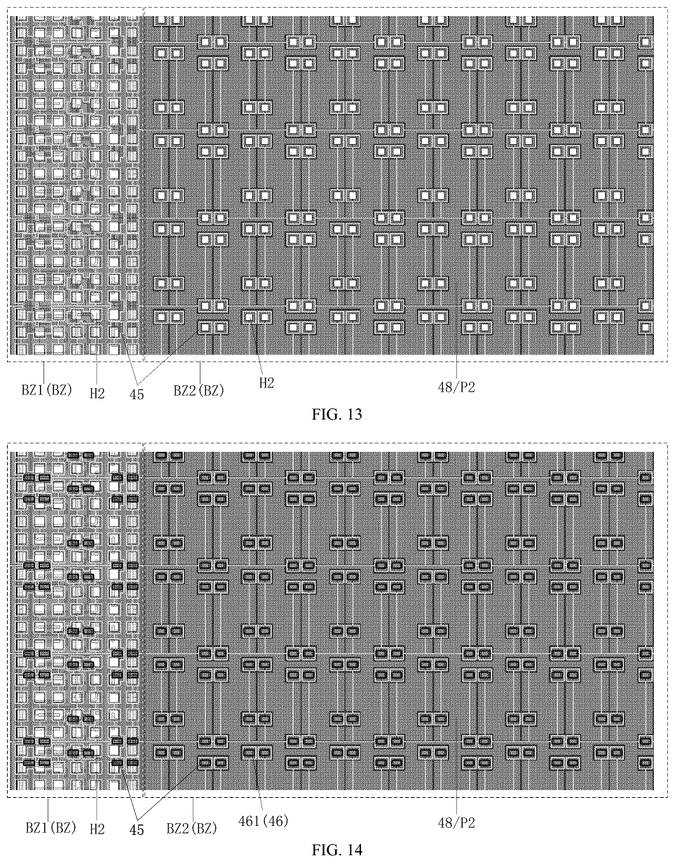

Referring to FIG. 14, which schematically shows a schematic diagram of a planar structure of a stacked structure constructed by a first conductive layer 42, a flat layer 44, a second conductive layer 48, a pixel definition layer 45, and a spacer layer 46. As shown in FIG. 4 or FIG. 14, the second conductive layer 48 includes a second lapping pattern P2, and the orthographic projections of the second lapping pattern P2, the pixel definition layer 45, and the spacer layer 46 on the substrate 41 respectively do not overlap; the orthographic projections of the third conductive layer 49 and the second lapping pattern P2 on the substrate 41 overlap, and the third conductive layer 49 and the second lapping pattern P2 lap each other.

As shown in FIG. 4 or FIG. 14, the second lapping pattern P2 is an area of the second conductive layer 48 that is not covered by the pixel definition layer 45 and the spacer layer 46. The transmission of a signal from the second conductive layer 48 to the third conductive layer 49 can be achieved by arranging the third conductive layer 49 to lap the second lapping pattern P2.

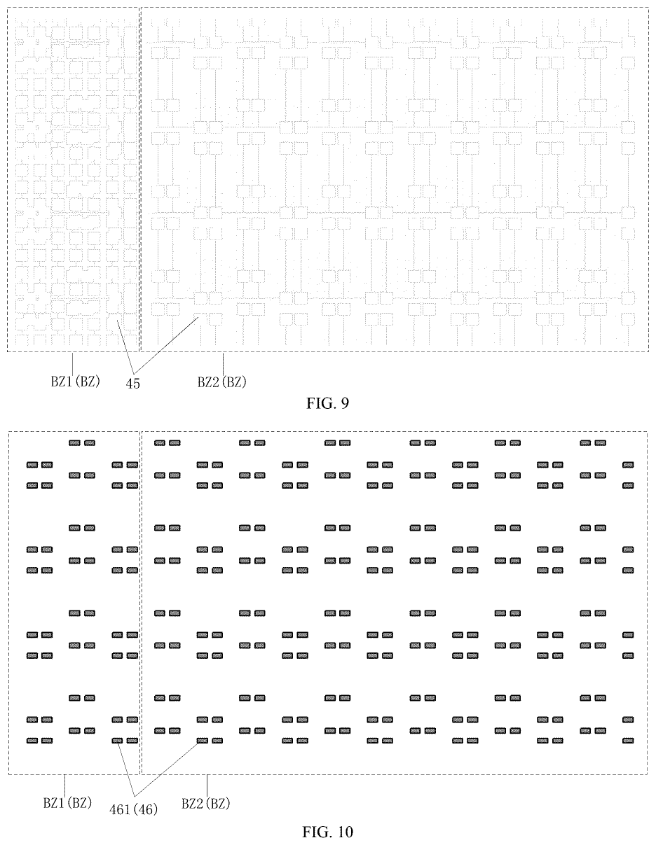

Referring to FIG. 9, which schematically shows a schematic diagram of a planar structure of a kind of pixel definition layer 45. As shown in FIG. 4, FIG. 9, or FIG. 13, in the pixel definition layer 45, a pattern for covering the edge of the second opening H2 is disposed only at an edge position of the second opening H2, and the pixel definition layers 45 in other areas are all dug up, so that the lapping area between the third conductive layer 49 and the second conductive layer 48 can be increased and the IR Drop effect can be reduced.

Alternatively, as shown in FIGS. 7 and 11, the orthographic projection of the flat layer 44 on the substrate 41 covers the orthographic projection of the first opening H1 on the substrate 41 and its boundary.

By disposing the flat layer 44 to cover the edge of the first opening H1, it may avoid etching away materials, such as aluminum, in the first conductive layer 42 during the subsequently wet etching process of a film layer (e.g., the second conductive layer 48), and to prevent the titanium disposed on the surface of the aluminum material from falling off to create a dark spot.

It needs to be noted that in an actual process, due to the limitation of process conditions or other factors, the same in the above features cannot be completely the same, and there may be some deviations. Therefore, the same relationship between the above-mentioned features is within the scope of the present disclosure as long as the above-mentioned conditions are substantially met. For example, the above-mentioned same may be the same as permitted within the allowable range of errors.

The present disclosure also provides a display device including: the display baseplate as provided in any of the implementation modes; a driving integrated circuit configured to provide a driving signal to the display baseplate; and a power supply circuit configured to supply power to the display baseplate.

Those skilled in the art can understand that the display device has the advantages of the above-mentioned display baseplate.

The display device provided by the present disclosure has a function of displaying an image (i.e., a picture). The display device may include a displayer or a product including a displayer. Among other things, the displayer may be a flat panel display (FPD), a microdisplay, etc. The displayer may be a transparent displayer or an opaque displayer if it is divided according to a scene whether a user can see behind the displayer. The displayer may be a flexible displayer or an ordinary displayer (which may be referred to as a rigid displayer) if it is divided according to whether the displayer can be bent or curled. Illustratively, a product including the displayer may include: a computer, a television, a billboard, a laser printer with a displaying function, a telephone, a mobile phone, electronic paper, a personal digital assistant (PDA), a laptop computer, a digital camera, a tablet computer, a notebook computer, a navigator, a portable camcorder, a viewfinder, a vehicle, a large area wall, a screen of a theater, or a stadium sign, etc.

The present disclosure also provides a manufacturing method for a display baseplate. With reference to FIGS. 3 and 4, the display baseplate includes an active area AA and a border area BZ located on at least one side of the active area AA. The manufacturing method for a display baseplate in the border area BZ includes:
step S01: providing a substrate 41; and
step S02: forming a first conductive layer 42 on one side of the substrate 41.

As shown in FIG. 6, at least one first opening H1 is disposed on the first conductive layer 42, and the orthographic projection of the first conductive layer 42 on the substrate 41 does not overlap with the orthographic projection of the first opening H1 on the substrate 41.

The display baseplate provided by any of the above implementation modes can be manufactured by using the manufacturing method provided by the present disclosure.

In some illustrative implementation modes, the border area BZ includes a first wiring area BZ1 and a second wiring area BZ2, and the first wiring area BZ1 is located between the active area AA and the second wiring area BZ2.

Accordingly, the manufacturing method of the display baseplate of the border area BZ may further include:
step S03: forming a flat layer 44 on one side of the first conductive layer 42 away from the substrate 41. Referring to FIG. 11, which shows a schematic diagram of a planar structure of the display baseplate with the flat layer manufactured.

The orthographic projection of the flat layer 44 on the substrate 41 covers the first wiring area BZ1, and the orthographic projection of the first opening H1 on the substrate 41 and its boundary.

Step S04: forming a second conductive layer 48 on one side of the flat layer 44 away from the substrate 41. Referring to FIG. 12, which shows a schematic diagram of a planar structure of the display baseplate with the second conductive layer 48 manufactured.

A second opening H2 is disposed on the second conductive layer 48, the orthographic projection of the second conductive layer 48 on the substrate 41 does not overlap with the orthographic projection of the second opening H2 on the substrate 41, and the orthographic projection of the second opening H2 on the substrate 41 is within the range of the orthographic projection of the flat layer 44 on the substrate 41.

Step S05: forming a pixel definition layer 45 on one side of the second conductive layer 48 away from the substrate 41. Referring to FIG. 13, which shows a schematic diagram of a planar structure of display baseplate with the pixel definition layer 45 manufactured.

The orthographic projection of the pixel definition layer 45 on the substrate 41 covers the orthographic projection of the second opening H2 on the substrate 41 and its boundary. The orthographic projection of the pixel definition layer 45 on the substrate 41 is within the range of the orthographic projection of the flat layer 44 on the substrate 41.

Step S06: forming a spacer layer 46 on one side of the pixel definition layer 45 away from the substrate 41. Referring to FIG. 14, which shows a schematic diagram of a planar structure of the display baseplate with the spacer layer 46 manufactured.

The spacer layer 46 includes: a plurality of first spacer columns 461 located in the border area and separated from each other, and a plurality of second spacer columns (not shown in the figures) located in the active area and separated from each other. The first spacer column 461 is disposed in both the first wiring area BZ1 and the second wiring area BZ2.

The orthographic projection of the first spacer column 461 on the substrate 41 is within the range of the orthographic projection of the pixel definition layer 45 on the substrate 41.

Thereafter, a third conductive layer 49 and an encapsulation glass 43 may also be formed on one side of the spacer layer 46 away from the substrate 41, resulting in the display baseplate as shown in FIG. 4.

Each embodiment in the specification is described in a progressive manner. Each embodiment focuses on the differences from other embodiments. The same and similar parts between each embodiment can be referred to each other.

Finally, it should also be noted that in the specification, relational terms such as the first and second are only used to distinguish one entity or operation from another entity or operation, and do not necessarily require or imply any such actual relationship or order between these entities or operations. Moreover, the terms “including”, “comprising” or any other variation thereof are intended to cover non-exclusive inclusion, so that a process, method, commodity or equipment that includes a series of elements not only includes those elements, but also includes other elements that are not explicitly listed, or also includes elements inherent in such process, method, commodity or equipment. In the absence of further restrictions, the elements defined by the statement “including a . . . ” do not exclude the existence of other identical elements in the process, method, commodity or equipment including the said elements.

A display baseplate, a manufacturing method thereof and a display device provided by the present disclosure are described in detail above. Specific examples are used to illustrate the principles and implementation of the present disclosure, and the description of the above embodiments is only used to help understand the methods and core ideas of the present disclosure. At the same time, for those skilled in the art, according to the idea of the present disclosure, there will be changes in the specific implementation mode and application scope. To sum up, the content of this specification should not be understood as a limitation of the present disclosure.

Those skilled in the art will easily think of other embodiments of the present disclosure after considering the description and practicing the invention disclosed herein. The present disclosure is intended to cover any variant, use or adaptive change of the present disclosure. These variants, uses or adaptive changes follow the general principles of the present disclosure and include the common knowledge or commonly used technical means in the technical field not disclosed in the present disclosure. The specification and the embodiments are only regarded as illustrative. The true scope and spirit of the present disclosure are indicated by the following claims.

It should be understood that the present disclosure is not limited to the precise structure described above and shown in the drawings, and various modifications and changes can be made without departing from its scope. The scope of the present disclosure is limited only by the appended claims.

The “one embodiment”, “embodiment” or “one or more embodiments” mentioned herein means that the specific features, structures or features described in combination with the embodiments are included in at least one embodiment of the present disclosure. In addition, please note that the word “in one embodiment” does not necessarily refer to the same embodiment.

A large number of specific details are described in the instructions provided here. However, it can be understood that the embodiments of the present disclosure can be practiced without these specific details. In some examples, the well-known methods, structures and techniques are not shown in detail so as not to obscure the understanding of this specification.

In the claims, any reference symbol between brackets shall not be constructed as a restriction on the claims. The word “including” does not exclude the existence of elements or steps not listed in the claims. The word “one” or “a/an” before a component does not exclude the existence of multiple such components. The present disclosure can be realized by means of hardware including several different elements and by means of a properly programmed computer. In the unit claims that list several devices, several of these devices can be embodied by the same hardware item. The use of the first, second, and third words does not indicate any order. These words can be interpreted as names.

Finally, it should be noted that: the above embodiments are provided only to illustrate the technical solutions of the present disclosure, not to limit it; while the present disclosure has been described in detail with reference to the foregoing embodiments, those of ordinary skills in the art should understand that: the technical solutions disclosed in the above-mentioned embodiments can still be modified, or some of the technical features can be replaced by equivalents; such modifications and substitutions do not make the essence of the corresponding technical solutions depart from the spirit and scope of the technical solutions of the embodiments of the present disclosure.

1. A display baseplate, comprising an active area and a border area located on at least one side of the active area, wherein the border area comprises:
a substrate; and
a first conductive layer disposed on one side of the substrate;
wherein at least one first opening is disposed on the first conductive layer, and an orthographic projection of the first conductive layer on the substrate does not overlap with an orthographic projection of the at least one first opening on the substrate.

2. The display baseplate according to claim 1, wherein the border area further comprises:
a flat layer disposed on one side of the first conductive layer away from the substrate;
a pixel definition layer disposed on one side of the flat layer away from the substrate; and
a spacer layer disposed on one side of the pixel definition layer away from the substrate, wherein the spacer layer comprises a plurality of first spacer columns separated from each other;
wherein orthographic projections of the plurality of first spacer columns on the substrate, an orthographic projection of the pixel definition layer on the substrate, and an orthographic projection of the flat layer on the substrate overlap with each other.

3. The display baseplate according to claim 2, wherein the orthographic projections of the plurality of first spacer columns on the substrate is within a range of the orthographic projection of the pixel definition layer on the substrate, and the orthographic projection of the pixel definition layer on the substrate is within a range of the orthographic projection of the flat layer on the substrate.

4. The display baseplate according to claim 2, wherein the border area further comprises:
a second conductive layer located between the flat layer and the pixel definition layer;
wherein at least one second opening is disposed on the second conductive layer, an orthographic projection of the second conductive layer on the substrate does not overlap with an orthographic projection of the at least one second opening on the substrate, and the orthographic projection of the at least one second opening on the substrate is within a range of the orthographic projection of the flat layer on the substrate.

5. The display baseplate according to claim 4, wherein the orthographic projection of the pixel definition layer on the substrate covers the orthographic projection of the at least one second opening on the substrate and its boundary.

6. The display baseplate according to claim 4, wherein the first conductive layer comprises a first lapping pattern, and orthographic projection of the first lapping pattern and the flat layer on the substrate do not overlap; the orthographic projections of the second conductive layer and the first lapping pattern on the substrate overlap, and the second conductive layer and the first lapping pattern lap each other.

7. The display baseplate according to claim 4, wherein a ratio of an area of the orthographic projection of the at least one second opening on the substrate to an overlapping area is greater than or equal to 0.15, and less than or equal to 0.6;
wherein the overlapping area is an area of a region where the orthographic projections of the flat layer and the second conductive layer on the substrate overlap with each other.

8. The display baseplate according to claim 4, wherein the border area further comprises:
a third conductive layer located on one side of the spacer layer away from the substrate;
wherein the second conductive layer comprises a second lapping pattern, and orthographic projections of the second lapping pattern, the pixel definition layer, and the spacer layer on the substrate do not overlap; orthographic projections of the third conductive layer and the second lapping pattern on the substrate overlap, and the third conductive layer and the second lapping pattern lap each other.

9. The display baseplate according to claim 2, wherein the orthographic projection of the flat layer on the substrate covers the orthographic projection of the at least one first opening on the substrate and its boundary.

10. The display baseplate according to claim 2, wherein the border area comprises a first wiring region and a second wiring region, the first wiring region is located between the active area and the second wiring region; the border area further comprises:
a drive circuit disposed between the substrate and the flat layer;
wherein the drive circuit is located in the first wiring area, the first conductive layer is located in the second wiring area, and the orthographic projection of the flat layer on the substrate covers the first wiring area.

11. The display baseplate according to claim 10, wherein the plurality of first spacer columns are located in the first wiring area and/or the second wiring area.

12. The display baseplate according to claim 2, wherein the spacer layer further comprises a plurality of second spacer columns separated from each other, the plurality of second spacer columns are located in the active area;
wherein a height of a surface of one side of the second spacer column away from the substrate is consistent with a height of a surface of one side of the first spacer column away from the substrate.

13. The display baseplate according to claim 12, wherein a distribution density of the first spacer column is less than or equal to a distribution density of the second spacer column in a direction parallel to a plane where the substrate is located.

14. The display baseplate according to claim 2, wherein the display baseplate further comprises an encapsulation area located on one side of the border area away from the active area; and
a minimum distance between the first spacer column and the encapsulation area in a direction parallel to a plane where the substrate is located is less than or equal to 600 microns.

15. The display baseplate according to claim 1, wherein a size of the first opening is greater than or equal to 3 microns and less than or equal to 30 microns in a direction parallel to a plane where the substrate is located.

16. The display baseplate according to claim 1, wherein a minimum distance between two first openings in a direction parallel to a plane where the substrate is located is greater than or equal to 10 microns.

17. The display baseplate according to claim 1, wherein a ratio of an area of the orthographic projection of the at least one first opening on the substrate and an area of the orthographic projection of the first conductive layer on the substrate is less than or equal to 0.5.

18. The display baseplate according to claim 1, wherein a shape of the orthographic projection of the first opening on the substrate comprises at least one of: polygons, chamfered polygons, circles, ellipses, and sectors.

19. A display device, comprising:
the display baseplate according to claim 1;
a driving integrated circuit configured to provide a driving signal to the display baseplate; and
a power supply circuit configured to supply power to the display baseplate.

20. A manufacturing method for a display baseplate, wherein the display baseplate comprises an active area and a border area located on at least one side of the active area, and the manufacturing method for the border area comprises:
providing a substrate; and
forming a first conductive layer on one side of the substrate; wherein at least one first opening is disposed on the first conductive layer, and an orthographic projection of the first conductive layer on the substrate does not overlap with the orthographic projection of the at least one first opening on the substrate.
